(19) United States
(12) Patent Application Publication
(10) Pub. No.: US 2025/0328798 A1
(43) Pub. Date: Oct. 23, 2025

(54) METHOD AND ARRANGEMENT FOR DRIVING QUBITS

(71) Applicant: IQM FINLAND OY, Espoo (FI)

(72) Inventors: Pasi LÄHTEENMÄKI, Espoo (FI); Aleksei SHARAFIEV, Munich (DE); Ugur YILMAZ, Munich (DE)

(21) Appl. No.: 18/868,507

(22) PCT Filed: May 25, 2022
(86) PCT No.: PCT/FI2022/050367

§ 371 Date: Nov. 22, 2024

(51) Int. Cl. G06N 10/40; H10N 60/12

(52) U.S. Cl. CPC G06N 10/40; H10N 60/12

(57) ABSTRACT

A quantum computing system comprises a qubit and a driving circuit for providing a stream of driving pulses to said qubit. The driving circuit is configured to produce said driving pulses as bipolar voltage pulses so that a driving voltage in each driving pulse deviates from zero to either positive or negative direction. The stream of driving pulses contains pulses of both polarities in a predetermined sequence.

### FIELD OF THE INVENTION

The invention is generally related to the technology of quantum computing. In particular the invention is related to the task of driving qubits, i.e. providing control signals that make qubits perform the desired operations related to quantum computing.

### BACKGROUND OF THE INVENTION

The qubits of a quantum computing system must be kept at a very low temperature, such as only some millikelvins, during operation. This is typically achieved by placing the QPU (Quantum Processing Unit) containing the qubits at the mixing chamber stage of a cryostat in which a dilution refrigerator produces and maintains the lowest temperature. To drive the qubits, i.e. to provide them with the control signals necessary to perform quantum computing, the standard approach has been to generate the driving signals as GHz-frequency waveforms in the room temperature environment and to feed in them to the cryostat using thermally anchored cabling.

Attempts to scale up the size (in number of qubits) of a quantum computing system introduce problems related to the generation of heat. The dilution refrigerator has a relatively low cooling power at the lowest temperatures, for which reason the structure of the system should allow for as little heat conduction as possible to the lowest temperature stages. As every signal path represents also a potential heat conduction path, the number of signal paths to and from the lowest temperature stage should remain as small as possible. Cables of the kind needed are also very expensive, which is another motivating factor for not allowing their number to increase too much.

In addition to heat conducted from warmer stages, also heat generated locally at the coldest stage loads the cooling arrangement. The circuitry used to drive the qubits should be such that it generates as little heat as possible through power dissipation.

Yet another factor to consider is the power consumption of the electronics located outside the cryostat, in the room temperature environment.

All these factors have driven the development of quantum computing systems towards building digitally controllable superconducting drivers and associated logic inside the cryogenic environment, next to the QPU. A known approach to building these kinds of circuits involves resistively shunted Single Flux Quantum (SFQ) technology, in which a stream of classical bits become represented by the presence or absence respectively of a phase slip across a Josephson junction in a given clock cycle. Each phase slip results in a voltage pulse whose time integral is precisely equal with the superconducting flux quantum. Each voltage pulse subjects the qubit to an incremental rotation on the Bloch sphere, so that (almost) arbitrary rotations can be produced by applying a corresponding sequence of pulses. However, the resistive shunts required in SFQ lead to dissipation levels that may easily become excessive in scaling up the number of qubits.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an objective to provide a method and an arrangement for driving qubits in a way that enables scaling up the size of the quantum computing system while avoiding the known problems that relate to heat load.

These and further advantageous objectives are achieved by driving the qubits with a continuous stream of adiabatically generated voltage pulses.

According to a first aspect, there is provided quantum computing system, comprising a qubit and a driving circuit for providing a stream of driving pulses to said qubit. The driving circuit is configured to produce said driving pulses as bipolar voltage pulses so that a driving voltage in each driving pulse deviates from zero to either positive or negative direction and the stream of driving pulses contains pulses of both polarities in a predetermined sequence.

According to an embodiment, said driving circuit is configured to produce said driving pulses so that the time integral of each driving pulse voltage equals the superconducting flux quantum h/2e, where h is the Planck constant and e is the elementary charge. This involves at least the advantage that the driving pulses can be made to have a well-controlled effect on the state of the driven qubit.

According to an embodiment, said driving circuit is configured to produce said driving pulses by repetitively causing a critical current through one or more Josephson junctions in said driving circuit to be temporarily exceeded. This involves at least the advantage that the driving pulses can be produced quasi adiabatically with minimal dissipation and very little generation of waste heat.

According to an embodiment, said driving circuit comprises a first current source, a second current source, a first inductive current path between said first current source and a first reference potential, and said one or more Josephson junctions coupled between said second current source and a second reference potential through respective second inductive current paths. Said first inductive current path may then be inductively coupled to said respective second inductive current paths. This involves at least the advantage that said driving pulses can be produced at a rate that is four times the frequency of an AC current conducted through the first inductive current path.

According to an embodiment, the polarity of each of said bipolar voltage pulses is selected by using a corresponding polarity of current pulses in the current produced by said second current source. This involves at least the advantage that essentially arbitrary patterns of pulses of the two polarities can be produced.

According to an embodiment, the quantum computing system comprises a transmission line between said driving circuit and said qubit for providing said bipolar voltage pulses to said qubit. This involves at least the advantage that the driving circuit can be placed relatively distant from the QPU chip housing the qubit, making it easier to handle the various temperature issues.

According to an embodiment, the quantum computing system comprises a terminating resistive impedance at the end of said transmission line distant from said driving circuit. This involves at least the advantage that reflections in the transmission line can be avoided, which enables high fidelity driving of the qubit.

According to an embodiment, said terminating resistive impedance is external to a quantum computing chip or quantum computing module on which said qubit is located. This involves at least the advantage that any dissipation that may occur in the terminating resistive impedance may be kept from interfering with the operation of the qubit and the driving circuit.

According to an embodiment, said qubit is one of a plurality of qubits in the quantum computing system. Said driving circuit may then be one of a plurality of driving circuits in the quantum computing system, and each of said plurality of driving circuits may be arranged to provide a respective one of said plurality of qubits with respective driving pulses as bipolar voltage pulses so that a driving voltage in each driving pulse deviates from zero to either positive or negative direction. This involves at least the advantage that the technology can be used to build a large quantum computing system with a large number of qubits and their respective driving circuits.

According to an embodiment, said plurality of qubits are located on a QPU chip and said plurality of driving circuits are located on a driving circuit chip separate from said QPU chip. This involves at least the advantage that the manufacturing of each of the driving circuits and the qubits may be optimised without having to use method steps and/or materials that would not be needed and that could interfere with the goal of making the chip as good as possible.

According to an embodiment, said QPU chip and said driving circuit chip are attached together in a stacked chip configuration. This involves at least the advantage that the distance between each driving circuit and its corresponding qubit can be made very small, which may allow minimising dissipation by leaving out the terminating resistive impedances or at least significantly increasing their value.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. In the drawings:

FIG. 1 illustrates a quantum computing system,

FIG. 2 illustrates a principle of using a stream of adiabatically generated voltage pulses to drive a qubit,

FIG. 3 illustrates an example embodiment of a circuit that can be used to realize the principle of FIG. 2,

FIG. 4 illustrates examples of signals used to generate voltage pulses,

FIG. 5 illustrates one possibility of selective use of voltage pulses to drive a qubit,

FIG. 6 illustrates one possibility of selective use of voltage pulses to drive a qubit,

FIG. 7 illustrates one possibility of selective use of voltage pulses to drive a qubit, and

FIG. 8 illustrates a quantum computing system according to an embodiment.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilised, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

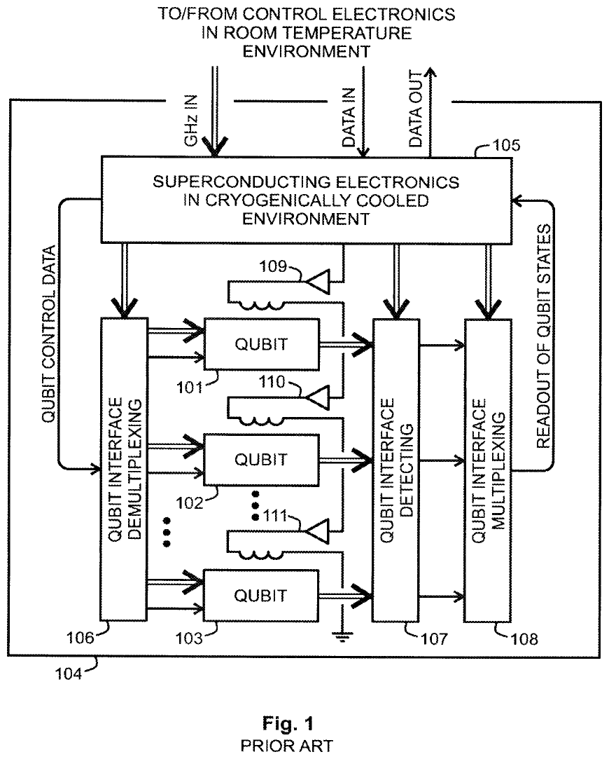

FIG. 1 illustrates schematically a quantum computing system that comprises N qubits, where N is a positive integer. Of said N qubits, three qubits 101, 102, and 103 are shown in FIG. 1. The outer perimeter 104 represents a cryogenically cooled environment for maintaining the qubits at the required very low temperature. In the embodiment shown in FIG. 1, the gigahertz-range frequencies needed to make the qubits perform quantum computing operations are brought in from control electronics located in the surrounding room temperature environment. It is also possible to controllably generate gigahertz-range frequencies within the cryogenically cooled environment, using for example the technology explained in a co-pending European patent application EP20712003.1, published as EP3939160.

Data that conveys the input information to be used in the quantum computing operations is brought in from the room temperature environment. Similarly, data that conveys the output results of the quantum computing operations are brought out to the room temperature environment. Both data streams are shown schematically in FIG. 1.

In addition to the qubits, the system comprises superconducting electronics in the cryogenically cooled environment. A bulk of such superconducting electronics is shown as block 105 in FIG. 1. Input couplings from said block to the qubits 101, 102, and 103 are shown as going through a qubit interface demultiplexing block 106 in FIG. 1. On the output side of the qubits, there are a qubit interface detecting block 107 for detecting the quantum states acquired by the qubits, as well as a qubit interface multiplexing block 108 for conveying the detection data further to the main superconducting electronics block 105. Additionally, FIG. 1 shows schematically some bias circuits 109, 110, and 111 for calibrating the qubits 101, 102, and 103 respectively.

FIG. 2 illustrates a part of a quantum computing system. The shown part comprises a qubit 201 and a driving circuit 202. The purpose of the driving circuit 202 is to provide a stream 203 of driving pulses to the qubit 201. In this respect, the general approach to driving the qubit 201 has some resemblance to the known SFQ principle: each driving pulse in the stream 203 may subject the qubit 201 to an incremental rotation on the Bloch sphere, so that (almost) arbitrary rotations can be produced by applying a corresponding sequence of pulses. However, there are important differences to the previously known technology that are described in more detail below. The generation of said pulses in the driving circuit utilizes two input signals, which are called the clocking frequency 204 and the control pattern 205 in FIG. 2.

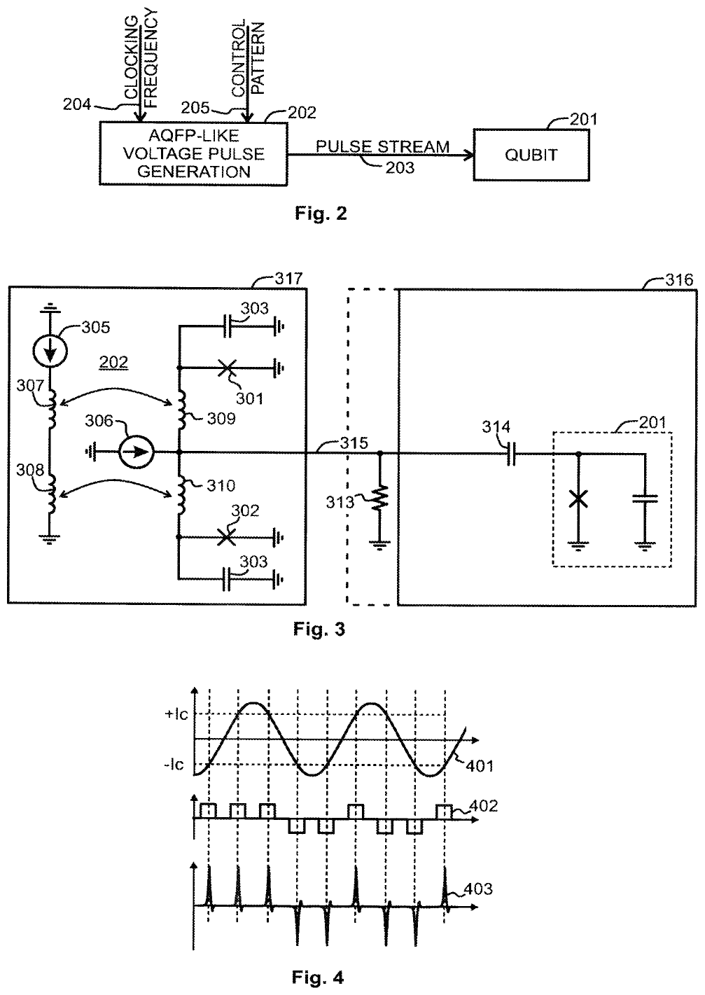

FIG. 3 shows one illustrative example of how the principle of FIG. 2 could be implemented in practice. In this case, the driving circuit 202 is configured to produce the driving pulses by repetitively causing a critical current through one or more Josephson junctions in the driving circuit 202 to be temporarily exceeded.

The driving circuit 202 of FIG. 3 comprises two Josephson junctions 301 and 302. A respective capacitance 303 or 304 is shown as coupled parallel to each Josephson junction 301 or 302, but these are merely representatives of the inherent capacitances that cannot be avoided and that must be taken into account in accurately analysing the behaviour of the circuit in FIG. 3.

A first current source 305 and a second current source 306 are shown as parts of the driving circuit 202. The actual current sourcing parts of the first and second current sources 305 and 306 are not necessarily part of the driving circuit 202 proper; the current sources can be located somewhere more distant so that only the currents they generate are brought in through suitable couplings to the driving circuit 202. Comparing to FIG. 2, the first current source 305 is configured to produce the clocking frequency 204 and the second current source 306 is configured to produce the control pattern 205.

A first inductive current path couples the first current source 305 to a reference potential which is here shown to be the ground potential. Along said first inductive current path are separately shown two inductances 307 and 308. Whether they are parts of the same inductive component or implemented as separate inductive components, and whether there are more inductances than those two along the first inductive current path is irrelevant for the following description.

The Josephson junctions 301 and 302 are coupled between the second current source 306 and a reference potential through respective second inductive current paths. In the example implementation of FIG. 3, an inductance 309 exists between the second current source 306 and the first Josephson junction 301 and another inductance 310 exists between the second current source 306 and the second Josephson junction 302.

The first inductive current path is inductively coupled to the respective second inductive current paths. This inductive coupling is schematically shown in FIG. 3 as a coupling between inductances 307 and 309 as well as a coupling between inductances 308 and 310. Due to these inductive couplings, a current that flows through the first inductive current path induces a corresponding current through the respective second inductive current paths. In other words, by making the first current source 305 generate an AC electric current of desired frequency and amplitude, one may “pump” energy across the inductive couplings into the second inductive current paths, where the pumped energy affects the currents through the respective Josephson junctions 301 and 302.

Each Josephson junction has a critical current, i.e. a parameter value that defines the upper limit of the magnitude of electric current that can flow through the junction. If a Josephson junction is subjected to an externally applied alternating current the peak amplitude of which is larger than the critical current, during each cycle (i.e. 2*pi phase rotation) of the alternating current its absolute magnitude will exceed the critical current value twice: at the peaks of the positive and negative half-wave of the AC current form. The absolute magnitude of the alternating current will be briefly equal to the critical current four times during each 2*pi phase rotation: on both sides of the peak of the positive half-wave and on both sides of the peak of the negative half-wave.

FIG. 4 shows three graphs. The top graph 401 shows the magnitude of an alternating current of the kind described above: its absolute magnitude exceed the critical current value Ic at the peaks of the positive and negative half-wave of the AC current form. In the following, we assume that the first current source 305, the first inductive current path 307-308, the second inductive current paths 309 and 310, and the inductive couplings between the current paths are used in an attempt to drive a current of this kind to each of the Josephson junctions 301 and 302.

Simultaneously, the second current source 306 is used to produce a pulsating current of the kind shown by the second graph 402 in FIG. 4. Said pulsating current consists of bipolar current pulses, i.e. brief pulses of either positive or negative current according to a predetermined pattern. In this example the output current of the second current source 306 returns to zero between each consecutive pulse, but this is not essential as the output current of the second current source 306 could simply toggle between positive and negative values according to said predetermined pattern.

It turns out that as a result, rapid voltage pulses occur across a terminating resistive impedance 313 of the transmission line 315 that couples the common point of the second current source 306 and the inductances 309 and 310 to the coupling capacitance 314 of the qubit 201. The third graph 403 in FIG. 4 illustrates said voltage pulses. Each of said voltage pulses occurs at the moment when the induced current illustrated by the first graph 401 crosses the +Ic or −Ic value in the positive or negative direction (see the vertical dashed lines in FIG. 4). The polarity of each of said voltage pulses follows the polarity of the corresponding current pulse in the output of the second current source 306, as shown by the second graph 402.

As there are two complementary pulse polarities, these can be designated as bit values in order to easily refer to pulse sequences in terms of bit patterns. For example, assuming a polarity convention in which a positive voltage pulse represents a “1” and a negative voltage pulse represents a “0”, the pulse sequence represented by the lowest graph 403 in FIG. 4 would be “111001001”.

Intuitively, the generation of the bipolar voltage pulses illustrated by the third graph 403 may be explained as follows. Each of the Josephson junctions 301 and 302 can only conduct an electric current smaller than or equal to the critical current Ic. Any larger current must be “dumped” somewhere, and as there is no local resistive shunt across any of the Josephson junctions 301 or 302, the only route for the dumped current is through the transmission line 315 and the terminating resistive impedance 313. In order to minimize reflections, the terminating resistive impedance 313 may be a 50 ohms impedance.

In general, and comparing to FIG. 2, the driving circuit 202 can be said to provide a stream of driving pulses to the qubit 201. More particularly, the driving circuit 202 is configured to produce said driving pulses as bipolar voltage pulses 403 so that a driving voltage in each driving pulse deviates from zero to either positive or negative direction and the stream 203 of driving pulses contains pulses of both polarities in a predetermined sequence.

By dimensioning the components and couplings suitably, the driving circuit 202 may be configured to produce said driving pulses so that the time integral of each driving pulse voltage equals the superconducting flux quantum h/2e, where h is the Planck constant and e is the elementary charge.

In FIG. 4 the voltage pulses 403 seem to come at relatively regular intervals. It should be noted, however, that this is so only because the amplitude of the induced current 401 happens to have such a value in relation to the critical current Ic that the graph 401 intersects the horizontal +Ic and −Ic lines at phase values of about pi/4, 3*pi/4, 5*pi/4, and 7*pi/4. It is by no means essential to make the voltage pulses come at regular intervals. If the amplitude of the induced current 401 was slightly smaller, the voltage pulses would come in pairs so that in FIG. 4 the second and third voltage pulses would have a short interval, then a longer interval would occur before the fourth and fifth voltage pulses would come in rapid succession, and so on. Similarly, if the amplitude of the induced current 401 was slightly larger, the first and second voltage pulses would have a short interval, then a longer interval would occur before the third and fourth voltage pulses would come in rapid succession, and so on.

FIG. 3 shows schematically the qubit 201 as being located on a QPU chip 316 and the driving circuit 202 as being located on a driving circuit chip 317 separate from said QPU chip 316. Concerning the terminating resistive impedance 313 one possibility is that it is not located on any of said two chips. A majority of all dissipation of power in the circuit takes place in the terminating resistive impedance 313, so for the purpose of keeping both of said chips as cold as possible, having the terminating resistive impedance 313 off-chip is particularly attractive. Any subgap resistance in the Josephson junctions is insignificant, so the driving circuit chip 317 may remain essentially at the temperature of the mixing chamber in the dilution refrigerator that is used to cool the quantum computing system.

Even the external dissipation, i.e. that occurring in the terminating resistive impedance 313, can be expected to be relatively low, in the order of 10 pW/Gbps. In order to estimate the total dissipation, one may assume that the qubit resonance frequency is about 5 GHz and that so-called fidelity optimized driving sequences (known from Kangbo Li, R. McDermott, Maxim G. Vavilov: “Scalable Hardware-Efficient Qubit Control with Single Flux Quantum Pulse Sequences”, arXiv: 1902.02911v1, 8 Feb. 2019) are used. The last-mentioned means a requirement of the bit rate represented by the voltage pulses 403 to be about five times the qubit frequency, i.e. about 25 Gbps, so the total dissipation may be around 250 pW per qubit. This is far below any conceivable alternative that could be accomplished by traditional resistively shunted SFQ drivers.

Taking the assumption of about 25 Gbps bit rate represented by the voltage pulses 403 and noting that four voltage pulses will occur per cycle in the clocking frequency 204, the magnitude of the clocking frequency should be around 6.25 GHZ. If the control pattern 205, i.e. the pulsed output current of the second current source 306 is produced using an oscillating triggering signal where each peak (positive or negative) triggers one current pulse, two current pulses will be generated per each cycle in the triggering signal. Again, assuming the 25 Gbps bit rate, the frequency of the triggering signal should thus be one half of that or about 12.5 GHz.

As the polarity of the corresponding voltage pulse (graph 403 in FIG. 4) will be determined by the polarity of the corresponding current pulse (graph 402 in FIG. 4), it is advantageous to generate the current pulses so that each current pulse has assumed a stable polarity at the moment when the induced current (graph 401 in FIG. 4) equals the critical current +Ic or −Ic. In FIG. 4, this is seen in that the vertical dashed lines occur essentially in the middle of each current pulse in graph 402. Generating the rising and falling edges in a triggering signal like that of graph 402 will inevitably involve some jitter, for which purpose it is not advisable to time the generation of any voltage pulse very close to any rising or falling edge of the current pulses.

A peculiar feature of the arrangement described above is that the stream 203 of driving pulse will remain on as long as the clocking frequency 204 remains active. At each moment when the induced current in the second inductive current paths momentarily equals the critical current, a voltage pulse will appear. Consequently, the qubit 201 will receive driving pulses all the time, irrespective of whether it should actually be driven for the purpose of performing a quantum computing operation.

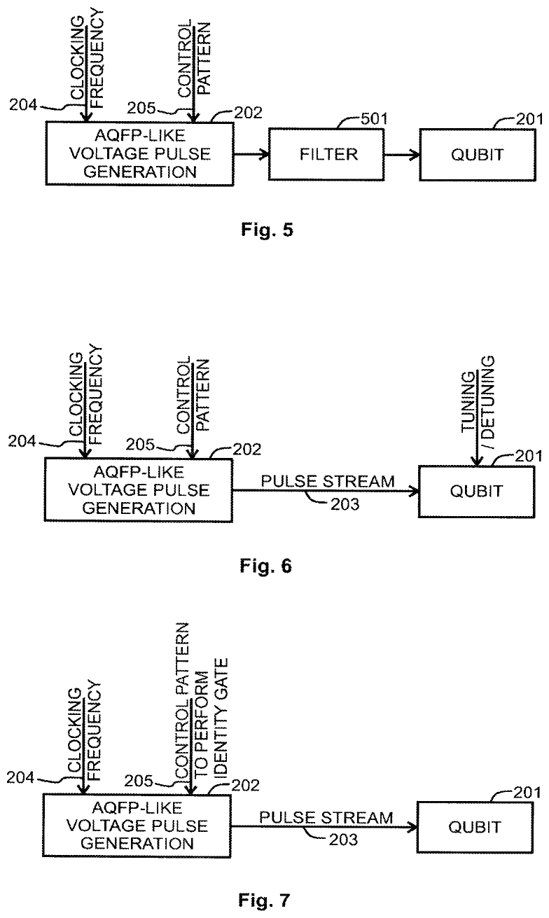

FIGS. 5 to 7 show a number of ways in which “unnecessary” driving of the qubit may be avoided. FIG. 5 represents filtering, in which a suitable attenuating filter 501 is placed along the transmission line between the driving circuit 202 and the qubit 201. Taken that the bit rate represented by the voltage pulses on the transmission line is far higher than the qubit frequency (25 Gbps vs. 5 GHz in the examples above), the control pattern 205 that defines the polarity of each voltage pulse may be selected so that the effective frequency of the stream of voltage pulses hits an attenuation band of the filter 501. For example, a sequence of voltage pulses represented by a bit pattern “1111111 . . . ” at 25 Gbps does not carry any significant energy on 5 GHZ and will therefore be mostly ignored by any qubit of resonance frequency around 5 GHZ.

FIG. 6 illustrates an alternative embodiment, according to which the qubit frequency is tuned. Due to its characteristics, the qubit 201 itself acts as a relatively effective bandpass filter, only accepting driving signals at frequencies within a narrow band around its resonance frequency. Tuning of the qubit 201 may be utilized to ensure that the bit rate represented by the voltage pulses on the transmission line is sufficiently far away from said narrow band around the qubit frequency, in which case the voltage pulses will have only a negligible net effect on the qubit 201.

FIG. 7 illustrates an alternative embodiment, in which the control pattern 205 is selected so that even if the voltage pulses in the pulse stream 203 do drive the qubit 201, they make it perform only repeated identity gates. For example, the pulse stream 203 may first convey a first bit pattern and immediately thereafter its inverse bit pattern, so that the net effect on the qubit state is zero.

It is possible to combine techniques such as those shown in FIGS. 5 to 7 in order to ensure that no unnecessary or unintentional driving of the qubit 201 will take place. For example, one may use a bit pattern that takes the effective frequency of the pulse stream far off the (possibly tuned) qubit frequency, and yet use immediately thereafter the inverse bit pattern that revokes any small effect that the actual bit pattern might still have had on the state of the qubit.

Concerning feasibility of operation, simulations were run with the jsim simulating software, using circuitry like that in FIG. 3, a qubit frequency 5 GHZ, and unoptimized continuous pulse driving at 10 Gbps. According to said simulations, a rotation of pi radians on the Bloch sphere is possible in approximately 10 nanoseconds and at a gate fidelity of approximately 99%. It is plausible that the gate fidelity can be increased to 99.99% by using the fidelity optimised pulse sequences mentioned earlier in this text and/or longer pulse trains. Assuming 100 kilo-ohms subgap dissipation temperature of 0.5 K in said simulation gave a signal to noise ratio of approximately −150 dBc/Hz at 5 GHZ, which is well sufficient for high fidelity gates.

According to an embodiment, AQFP pulse pattern logic, AQFP output driver, and the QPU chip constitute an integrated module. A prerequisite for keeping said circuits from interfering with each other is to ensure that the (presumably large and complex) AQFP control circuitry does not heat the qubits too much. In such an embodiment, it may be possible to drive the qubits without the 50 ohm terminating resistive impedance, or in principle without any terminating shunts whatsoever. This in turn may result in theoretically optimal power dissipation for a combined QPU and AQFP control stack. As an alternative, if some resistance is still needed due to e.g. stability reasons, a much larger resistive impedance like in the order of 500 ohm could be used, which would again help to reduce dissipation.

Leaving out the terminating shunts (or replacing them with ones of larger resistance) may become more feasible if the physical distance between the AQFP output stage and the qubit can be made short enough relative to the frequencies involved, so that reflections will not play a role. Since the AQFP output has mainly imaginary valued rather than real valued impedance, the coupling capacitor of the qubit could potentially be increased without increasing Purcell decay, thus allowing better power coupling. This would be particularly beneficial if qubit T1-times were to increase significantly from the levels known at the time of writing this text. Traditional driving would require weaker coupling to real valued impedance in order to support higher T1-times and simultaneously higher drive powers in order to be able to sustain gate speed. AQFP driver would not be limited by this as much.

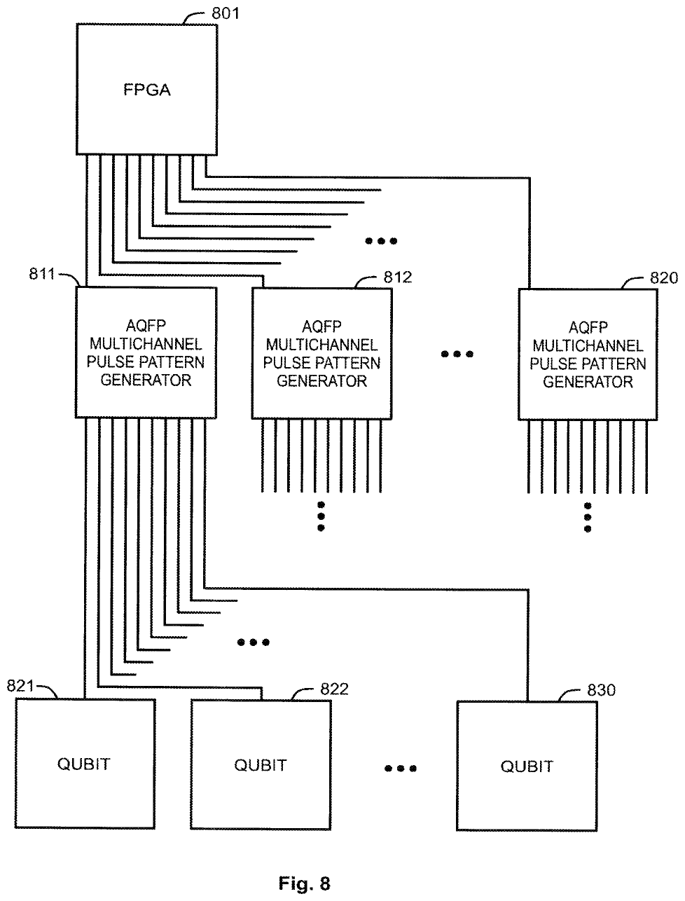

FIG. 8 illustrates schematically one possible way of arranging a qubit interface demultiplexing part that could be used to drive at least 100 qubits. The FPGA (Field Programmable Gate Array) 801 at the top has ten output channels, each coupled to provide output signals to a respective one of ten AQFP-based multichannel pulse pattern generators 811 to 820. Each multichannel pulse pattern generator 811 to 820 in turn has ten output channels, topologically corresponding to the transmission line 315 in FIG. 5, each coupled to provide the stream of driving pulses to a respective qubit 821 to 830.

The technology described above may allow pushing the driving-related dissipation so low that even very large quantum computing systems with thousands, tens of thousands, or even millions of qubits. As a rough estimate, an average of 10000 switching elements may be needed to control a single qubit, including readout, feedback, reset, and the like. Autonomic error correction may prove to be more power efficient than feedback-based, but feedback is assumed to be present for the moment. A rate of 25 GHZ may be assumed for flipping bits on the average, and while some computation may be reversible by nature, which would allow average dissipation less than the Landauer limit, it is safe to assume a dissipation of at least the Landauer limit E=k_{B}T ln2 amount of energy per bit flip per gate on the average.

According to a further assumption, the DC biases can be produced with persistent current switches which dissipate zero power in the steady state, so this part of the arrangement does not pose any dissipation-related problems in scaling up the size. Yet another assumption is operating a QPU that utilizes all-rf perfect off two qubits gates, which then allows utilizing static couplers. Consequently, there is no separate driving for couplers needed, so the discussion may be limited to just single qubits and two-qubit gates are done with particular pulse-sequences driven simultaneously to two individual qubits. This scheme may also facilitate static qubits, which may allow a much higher degree of immunity to flux noise.

The number of 10000 switching elements is based on a comparison to early microprocessors like the 6502, which had 3218 transistors, and assuming some excess for memory and the like. It should be noted, though, that the dissipation estimate may be even somewhat pessimistic: memory can for the most part function reversibly and need not dissipate energy except when erasing bits. Additionally, some of the dissipation related to erasing could possibly be carried out of the cryostat, if it proves to be possible to dump the excess energy during erasure via a cable to room temperature, for example via interaction with the AQFP clock.

The cryostat may have a cooling power of, say, 300 microwatts when operating at 30 mK, which should be cold enough for maintaining low enough a thermal population. Calculating with these values, one could build a quantum computing system with about 4000000 qubits before running into dissipation-related technical limits. According to the assumptions, one would do most of the processing within the cryostat with AQFP right next to the QPU, so only a relatively small number of cables would go in and out of the cryostat. These cables could be used mainly for programming the AQFP logic with predetermined programs and, at the end of the computation, for reading out the statistics. No real time driving signals (or very few of them) would be carried by said cables, which means that the related heating issues would also remain at an acceptable level.

It is obvious to a person skilled in the art that with the advancement of technology, the basic idea of the invention may be implemented in various ways. The invention and its embodiments are thus not limited to the examples described above, instead they may vary within the scope of the claims.

1. A quantum computing system, comprising a qubit and a driving circuit for providing a stream of driving pulses to said qubit, wherein the driving circuit is configured to produce said driving pulses as bipolar voltage pulses so that a driving voltage in each driving pulse deviates from zero to either positive or negative direction and the stream of driving pulses contains pulses of both polarities in a predetermined sequence.

2. The quantum computing system of claim 1, wherein said driving circuit is configured to produce said driving pulses so that a time integral of each driving pulse voltage equals the superconducting flux quantum h/2e, where h is the Planck constant and e is the elementary charge.

3. The quantum computing system of claim 1, wherein said driving circuit is configured to produce said driving pulses by repetitively causing a critical current through one or more Josephson junctions in said driving circuit to be temporarily exceeded.

4. The quantum computing system of claim 3, wherein said driving circuit comprises:
a first current source and a second current source,
a first inductive current path between said first current source and a first reference potential, and
said one or more Josephson junctions coupled between said second current source and a second reference potential through respective second inductive current paths;
wherein said first inductive current path is inductively coupled to said respective second inductive current paths.

5. The quantum computing system of claim 4, wherein the polarity of each of said bipolar voltage pulses is selected by using a corresponding polarity of current pulses in the current produced by said second current source.

6. The quantum computing system of claim 1, comprising a transmission line between said driving circuit and said qubit for providing said bipolar voltage pulses to said qubit.

7. The quantum computing system of claim 6, comprising a terminating resistive impedance at an end of said transmission line distant from said driving circuit.

8. The quantum computing system of claim 7, wherein said terminating resistive impedance is external to a quantum computing chip or quantum computing module on which said qubit is located.

9. The quantum computing system of claim 1, wherein:
said qubit is one of a plurality of qubits in the quantum computing system,
said driving circuit is one of a plurality of driving circuits in the quantum computing system, and
each of said plurality of driving circuits is arranged to provide a respective one of said plurality of qubits with respective driving pulses as bipolar voltage pulses so that a driving voltage in each driving pulse deviates from zero to either positive or negative direction.

10. The quantum computing system of claim 9, wherein:
said plurality of qubits are located on a QPU chip and
said plurality of driving circuits are located on a driving circuit chip separate from said QPU chip.

11. The quantum computing system of claim 10, wherein said QPU chip and said driving circuit chip are attached together in a stacked chip configuration.

12. The quantum computing system of claim 2, wherein said driving circuit is configured to produce said driving pulses by repetitively causing a critical current through one or more Josephson junctions in said driving circuit to be temporarily exceeded.

13. The quantum computing system of claim 2, comprising a transmission line between said driving circuit and said qubit for providing said bipolar voltage pulses to said qubit.

14. The quantum computing system of claim 3, comprising a transmission line between said driving circuit and said qubit for providing said bipolar voltage pulses to said qubit.

15. The quantum computing system of claim 4, comprising a transmission line between said driving circuit and said qubit for providing said bipolar voltage pulses to said qubit.

16. The quantum computing system of claim 2, wherein:
said qubit is one of a plurality of qubits in the quantum computing system,
said driving circuit is one of a plurality of driving circuits in the quantum computing system, and
each of said plurality of driving circuits is arranged to provide a respective one of said plurality of qubits with respective driving pulses as bipolar voltage pulses so that a driving voltage in each driving pulse deviates from zero to either positive or negative direction.

17. The quantum computing system of claim 3, wherein:
said qubit is one of a plurality of qubits in the quantum computing system,
said driving circuit is one of a plurality of driving circuits in the quantum computing system, and
each of said plurality of driving circuits is arranged to provide a respective one of said plurality of qubits with respective driving pulses as bipolar voltage pulses so that a driving voltage in each driving pulse deviates from zero to either positive or negative direction.
